(19) United States
(12) Patent Application Publication
(10) Pub. No.: US 2020/0251683 A1
(43) Pub. Date: Aug. 6, 2020

(54) ORGANIC LIGHT EMITTING DIODE DISPLAY PANEL AND PREPARATION METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jiajia SUN, Wuhan, Hubei (CN)

(21) Appl. No.: 16/475,385

(22) PCT Filed: Apr. 2, 2019
(86) PCT No.: PCT/CN2019/080911

§ 371 Date: Jul. 2, 2019

(30) Foreign Application Priority Data
Jan. 31, 2019 (CN) 201910095008.3

(51) Int. Cl. H01L 51/52; H01L 27/32; H01L 51/00; H01L 51/56

(52) U.S. Cl. CPC H01L 51/5253; H01L 27/3244; H01L 51/0097; H01L 2227/323; H01L 51/56; H01L 2251/5338; H01L 51/0017

(57) ABSTRACT

The present invention provides an organic light-emitting diode (OLED) display panel including a base substrate, a thin film transistor substrate disposed on the base substrate, a light emitting layer disposed on the thin film transistor substrate, and an encapsulation layer on the thin film transistor substrate and covering the light emitting layer; wherein a side of the thin film transistor substrate contacting the encapsulation layer is provided with a groove, and a portion of the encapsulation layer is located in the grooves.

### BACKGROUND OF INVENTION

### Field of Invention

The present invention relates to the field of display technologies, and in particular, to an organic light-emitting diode (OLED) display panel and a method of fabricating the same.

### Description of Prior Art

Compared with traditional liquid-crystal displays (LCDs), organic light-emitting diode (OLED) devices have advantages of being light in weight, have wide viewing angles, fast response times, low temperature resistance, and high luminous efficiency. Therefore, OLED devices have been regarded as the next generation of new display technologies in display industry. In particular, OLEDs can be fabricated into bendable and flexible display screens on flexible substrates.

With development of current OLED industry, dynamic bending has become a research hotspot. The current OLED display panel mainly includes a substrate, an array substrate, a light-emitting segment, and a thin film encapsulation structure, wherein the thin film encapsulation structure often uses an inorganic/organic/inorganic stack to form a film structure.

However, because a connection between a lowermost layer of the thin film encapsulation structure and the array substrate is not tight enough, the thin film encapsulation structure is easily peeled off from the array substrate as the number of bending times of the OLED display panel increases.

### SUMMARY OF INVENTION

An organic light-emitting diode (OLED) display panel is provided, including: a base substrate; a thin film transistor substrate disposed on the base substrate; a light emitting layer disposed on the thin film transistor substrate; an encapsulation layer disposed on the thin film transistor substrate and covering the light emitting layer; wherein grooves are defined in a side of the thin film transistor substrate in contact with the encapsulation layer, a part of the encapsulation layer is located in the grooves, and the encapsulation layer includes a first inorganic layer covering the light emitting layer, an organic layer disposed on the first inorganic layer, and a second inorganic layer covering the first inorganic layer and the organic layer, a part of the second inorganic layer being located in the grooves.

Further, the grooves are gradually tapered toward the encapsulation layer.

Further, a shape of a longitudinal section of each of the grooves is a positive trapezoidal shape or a teardrop shape.

Further, the grooves surround the light emitting layer by at least one circle.

Further, a shape of at least one circle of the grooves in whole is a parallelogram.

Further, each side of at least one circle of the grooves has a wave shape.

Further, each side of the cross section of the at least one of the grooves has a sinus wave shape.

An organic light-emitting diode (OLED) display panel is further provided, including: a base substrate; a thin film transistor substrate disposed on the base substrate; a light emitting layer disposed on the thin film transistor substrate; an encapsulation layer disposed on the thin film transistor substrate and covering the light emitting layer; wherein grooves are defined in a side of the thin film transistor substrate in contact with the encapsulation layer, and a part of the encapsulation layer is located in the grooves.

Further, the grooves are gradually tapered toward the encapsulation layer.

Further, a shape of a longitudinal section of each of the grooves is a positive trapezoidal shape or a teardrop shape.

Further, the grooves surround the light emitting layer by at least one circle.

Further, a shape of at least one circle of the grooves is a parallelogram.

Further, each side of at least one circle of the grooves has a wave

Further, each side of at least one circle of the grooves has a sinus wave shape.

The present invention also provides a method of fabricating an organic light-emitting diode (OLED) display panel, including the following steps:

S10, forming a thin film transistor substrate on a base substrate;

S20, forming a light-emitting layer on the thin film transistor substrate;

S30, forming grooves on an upper surface of the thin film transistor substrate;

S40, forming an encapsulation layer filling the grooves and covering the light emitting layer on the thin film transistor substrate.

Further, in the step S30, the thin film transistor substrate is etched using an etching solution to form the grooves.

Further, the grooves are gradually tapered toward the encapsulation layer.

The encapsulation layer is engaged with the inorganic layer on the thin film transistor substrate through the grooves, thereby increasing the connection strength between the encapsulation layer and the thin film transistor substrate, preventing the encapsulation layer from separating from the thin film transistor substrate during a bending process of the OLED display panel, and improving connection strength between layers in the encapsulation layer, thus preventing the layers from separating from each other in the encapsulation layer and improving a service life of the OLED display panel.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural diagram of an organic light-emitting diode (OLED) display panel according to an embodiment of the present invention.

FIG. 2 is a schematic structural diagram of an organic light-emitting diode (OLED) display panel according to another embodiment of the present invention.

FIG. 3 is a schematic plan view of an organic light-emitting diode (OLED) display panel according to an embodiment of the present invention.

FIG. 4 and FIG. 5 are schematic plan views of organic light-emitting diode (OLED) display panels according to other embodiments of the present invention.

FIG. 6 is a flow chart of a method of fabricating organic light-emitting diode (OLED) display panel according to an embodiment of the present invention.

FIG. 7 to FIG. 9 are schematic diagrams showing fabrication processes of an organic light-emitting diode (OLED) display panel according to an embodiment of the present invention.

Elements in the drawings are designated by reference numerals listed below.

10, substrate; 20, thin film transistor substrate; 21, inorganic layer; 30, light-emitting layer; 40, encapsulation layer; 41, first inorganic layer; 42, organic layer; 43, second inorganic layer; 50, groove.

### DETAILED DESCRIPTION OF PREFERRED EMBODIMENTS

The following description of the various embodiments is provided to illustrate the specific embodiments of the invention. The spatially relative directional terms mentioned in the present invention, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references. The spatially relative terms are intended to encompass different orientations in addition to the orientation as depicted in the figures.

The present invention is provided to solve the problem of an organic light-emitting diode (OLED) display panel of the prior art that a thin film encapsulation structure is easily peeled off from an array substrate as the number of bending times of the OLED display panel increases.

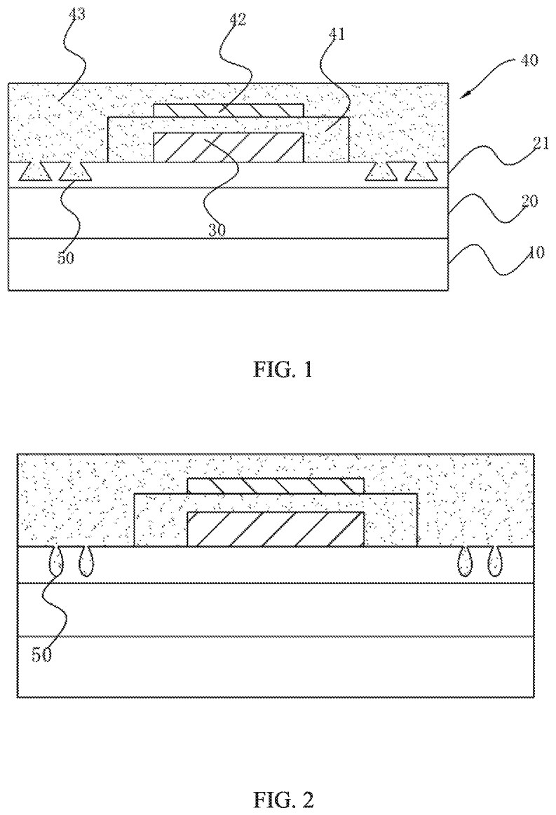

As shown in FIG. 1, an organic light-emitting diode (OLED) display panel includes a base substrate 10; a thin film transistor substrate 20 disposed on the base substrate 10; a light emitting layer 30 disposed on the thin film transistor substrate 20; and an encapsulation layer 40 disposed on the thin film transistor substrate 20 and covering the light emitting layer 30.

A plurality of grooves 50 are defined in a side of the thin film transistor substrate 20 in contact with the encapsulation layer 40, and a part of the encapsulation layer 40 is located in the grooves 50.

The encapsulation layer 40 includes a first inorganic layer 41 covering the light emitting layer 30, an organic layer 42 disposed on the first inorganic layer 41, and a second inorganic layer 43 covering the first inorganic layer 41 and the organic layer 42, a part of the second inorganic layer 43 located in the grooves 50.

It should be noted that the top layer of the thin film transistor substrate 20 is an inorganic layer 21, and the grooves 50 are defined in the inorganic layer 21.

The encapsulation layer 40 is engaged with the inorganic layer 21 on the thin film transistor substrate 20 through the grooves 50, thereby increasing the connection strength between the encapsulation layer 40 and the thin film transistor substrate 20, preventing the encapsulation layer 40 from separating from the thin film transistor substrate 20 during a bending process of an organic light-emitting diode (OLED) display panel, and improving connection strength between layers in the encapsulation layer 40, thus preventing the layers from separating from each other in the encapsulation layer 40 and improving service life of the OLED display panel.

Specifically, the grooves 50 are gradually tapered toward the encapsulation layer 40.

The encapsulation layer 40 and the inorganic layer 21 are engaged with each other through the grooves 50, thereby achieving greater connection strength and preventing the encapsulation layer 40 from being separated from the thin film transistor substrate 20 during a bending process of the OLED display panel.

Further, in an embodiment, a shape of a longitudinal section of each of the grooves 50 is a positive trapezoidal shape.

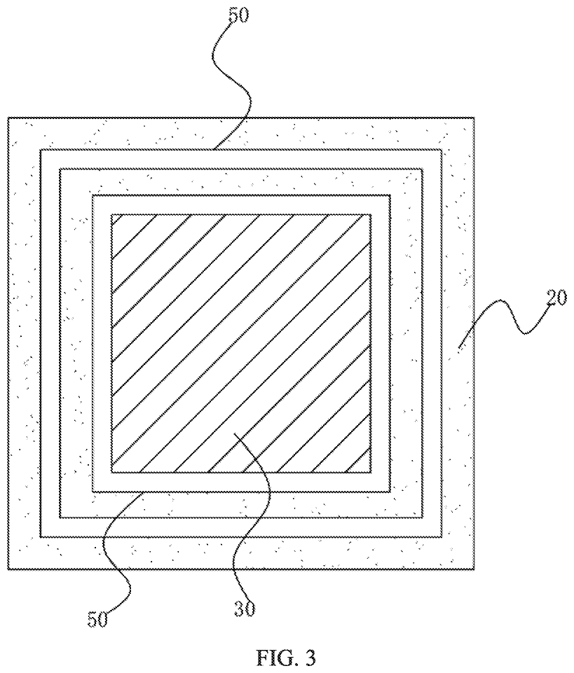

It should be noted that, in another embodiment, as shown in FIG. 2, a shape of a longitudinal section of each of the grooves 50 is a teardrop shape.

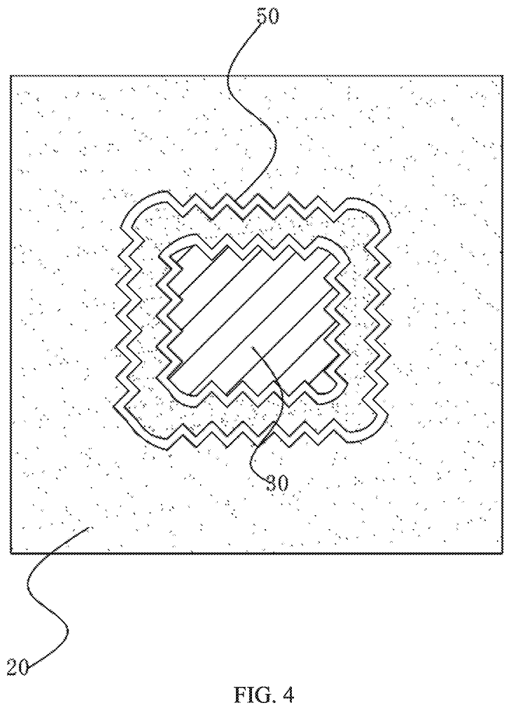

As shown in FIG. 3, the grooves 50 surround the light emitting layer 30 by at least one circle, and the grooves 50 are sequentially arranged in a direction away from the light emitting layer 30.

By providing the grooves 50 along a periphery of the light-emitting layer 30, lengths of the grooves 50 are increased, and the connection strength between the encapsulation layer 40 and the thin film transistor substrate 20 is thereby further enhanced.

It should be noted that, although only two grooves 50 are illustrated in FIG. 3. However, in actual implementation, the number of the grooves 50 may also be three, four, or more.

As shown in FIG. 3, in an embodiment, a shape of at least one circle of the grooves 50 in whole is a parallelogram.

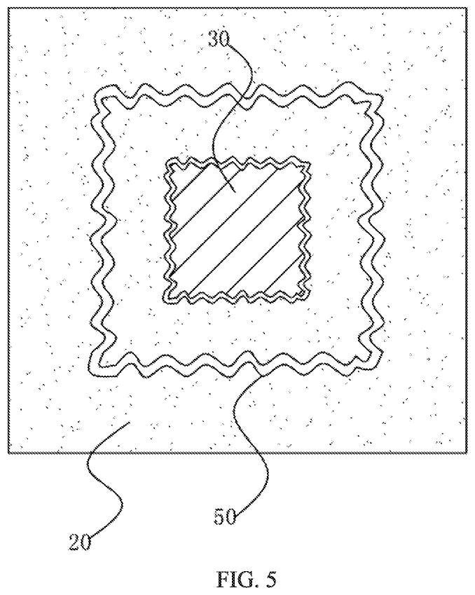

As shown in FIGS. 4 and 5, in other embodiments, each side of at least one circle of the grooves 50 has a wave shape.

Further, each side of at least one circle of the grooves 50 has a broken-line wave shape (as shown in FIG. 4) or a sinus wave shape (as shown in FIG. 5).

FIG. 3 only illustrates the case where the shape of at least one circle of the grooves 50 in whole is a parallelogram, and FIGS. 4 and 5 only illustrate the cases where each side of at least one circle of the grooves 50 has a wave shape. It should be noted that, in actual implementation, when the number of the grooves 50 are two or more, the grooves 50 of different shapes may be disposed in combination. For example, the shape of the cross section of one of the grooves is a parallelogram, while each side of the cross section of another one of the grooves has a wave shape.

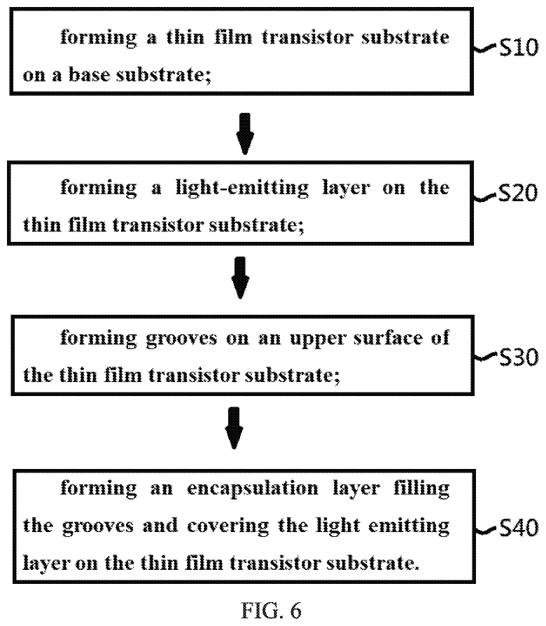

Based on the above OLED display panel, the present invention further provides a method of fabricating an organic light-emitting diode (OLED) display panel. As shown in FIG. 6, the method of fabricating an organic light-emitting diode (OLED) display panel includes the following steps.

S10, forming a thin film transistor substrate 20 on a base substrate 10;

S20, forming a light-emitting layer 30 on the thin film transistor substrate 20;

S30, forming grooves 50 on an upper surface of the thin film transistor substrate 20; and

S40, forming an encapsulation layer 40 filling the grooves 50 and covering the light emitting layer 30 on the thin film transistor substrate 20.

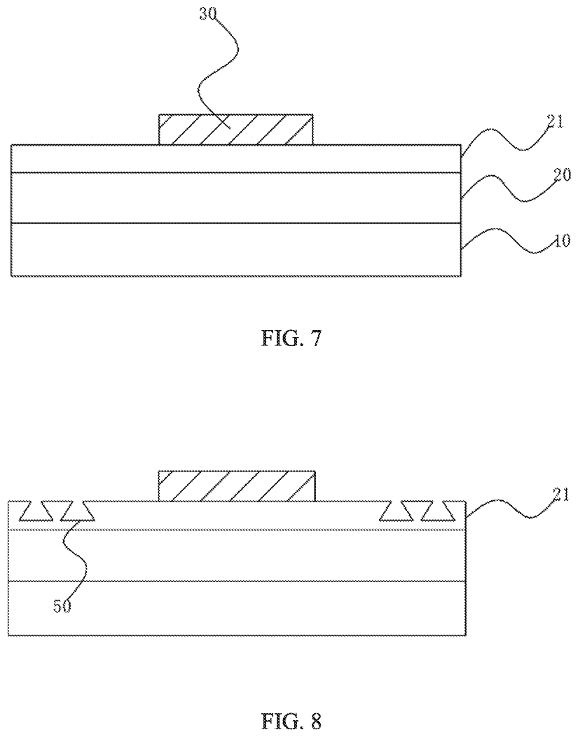

As shown in FIG. 7, after the thin film transistor substrate 20 is formed on the base substrate 10, the light-emitting layer 30 is formed on the thin film transistor substrate 20.

As shown in FIG. 8, regular grooves 50 are formed on the inorganic layer 21 located on the top layer of the thin film transistor substrate 20.

Specifically, in the step S30, the thin film transistor substrate 20 is etched by an etching solution to form the grooves 50.

Further, the grooves 50 are gradually tapered toward the encapsulation layer 40.

The grooves 50 are formed by wet etching, wherein wet etching time is prolonged, causing an etching liquid in the grooves 50 to continuously etch the inorganic layer 21 from both sides of the grooves 50, and a lower portion of the grooves 50 are more severely corroded than an upper portion, finally forming the grooves 50 that is gradually tapered toward the encapsulation layer 40.

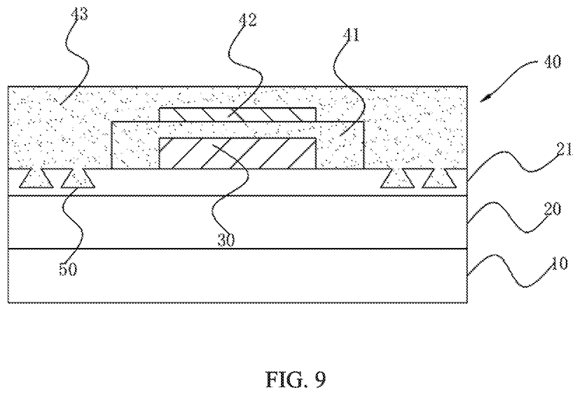

As shown in FIG. 9, a first inorganic layer 41 covering the light-emitting layer 30 is formed on the inorganic layer 21, and after the organic layer 42 is formed on the first inorganic layer 41, a second inorganic layer 43 covering the organic layer 42 and filling the grooves 50 is formed on the organic layer 42, to form the encapsulation layer 40.

The beneficial effect of the present invention is that the encapsulation layer 40 is engaged with the inorganic layer 21 on the thin film transistor substrate 20 through the grooves 50, thereby increasing the connection strength between the encapsulation layer 40 and the thin film transistor substrate 20, preventing the encapsulation layer 40 from separating from the thin film transistor substrate 20 during a bending process of the OLED display panel, and improving connection strength between layers in the encapsulation layer 40, thus preventing the layers from separating from each other in the encapsulation layer 40 and improving a service life of the OLED display panel.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. An organic light-emitting diode (OLED) display panel, comprising:
a base substrate;
a thin film transistor substrate disposed on the base substrate;
a light emitting layer disposed on the thin film transistor substrate;
an encapsulation layer disposed on the thin film transistor substrate and covering the light emitting layer;
wherein grooves are defined in a side of the thin film transistor substrate in contact with the encapsulation layer, a part of the encapsulation layer is located in the grooves, and the encapsulation layer includes a first inorganic layer covering the light emitting layer, an organic layer disposed on the first inorganic layer, and a second inorganic layer covering the first inorganic layer and the organic layer, a part of the second inorganic layer being located in the grooves.

2. The OLED display panel according to claim 1, wherein the grooves are gradually tapered toward the encapsulation layer.

3. The OLED display panel according to claim 2, wherein a shape of a longitudinal section of each of the grooves is a positive trapezoidal shape or a teardrop shape.

4. The OLED display panel according to claim 2, wherein the grooves surround the light emitting layer by at least one circle.

5. The OLED display panel according to claim 4, wherein a shape of at least one circle of the grooves in whole is a parallelogram.

6. The OLED display panel according to claim 4, wherein each side of at least one circle of the grooves has a wave shape.

7. The OLED display panel according to claim 6, wherein each side of the cross section of the at least one of the grooves has a sinus wave shape.

8. An organic light-emitting diode (OLED) display panel, comprising:
a base substrate;
a thin film transistor substrate disposed on the base substrate;
a light emitting layer disposed on the thin film transistor substrate;
an encapsulation layer disposed on the thin film transistor substrate and covering the light emitting layer;
wherein grooves are defined in a side of the thin film transistor substrate in contact with the encapsulation layer, and a part of the encapsulation layer is located in the grooves.

9. The OLED display panel according to claim 8, wherein the grooves are gradually tapered toward the encapsulation layer.

10. The OLED display panel according to claim 9, wherein a shape of a longitudinal section of each of the grooves is a positive trapezoidal shape or a teardrop shape.

11. The OLED display panel according to claim 9, wherein the grooves surround the light emitting layer by at least one circle.

12. The OLED display panel according to claim 11, wherein a shape of at least one circle of the grooves in whole is a parallelogram.

13. The OLED display panel according to claim 11, wherein each side of at least one circle of the grooves has a wave shape.

14. The OLED display panel according to claim 13, wherein each side of the cross section of the at least one of the grooves has a sinus wave shape.

15. A method of fabricating an organic light-emitting diode (OLED) display panel, comprising the following steps:
S10, forming a thin film transistor substrate on a base substrate;
S20, forming a light-emitting layer on the thin film transistor substrate;
S30, forming grooves on an upper surface of the thin film transistor substrate;
S40, forming an encapsulation layer filling the grooves and covering the light emitting layer on the thin film transistor substrate.

16. The method of fabricating the OLED display panel according to claim 15, wherein in the step S30, the thin film transistor substrate is etched by an etching solution to form the grooves.

17. The method of fabricating the OLED display panel according to claim 16, wherein the grooves are gradually tapered toward the encapsulation layer.
